(19) United States
(12) Patent Application Publication
(10) Pub. No.: US 2006/0227396 A1
(43) Pub. Date: Oct. 12, 2006

(54) Image forming apparatus and image forming method

(75) Inventors: Kousei Sugimoto, Atsugi-shi (JP); Izumi Kanai, Machida-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Ohta-ku (JP)

(21) Appl. No.: 11/398,619

(22) Filed: Apr. 6, 2006

(30) Foreign Application Priority Data
Apr. 12, 2005 (JP) 2005-114220
Mar. 1, 2006 (JP) 2006-054624

(51) Int. Cl. G03F 3/08

(52) U.S. Cl. 358/521; 358/519

(57) ABSTRACT

An image forming apparatus for executing gradation correction processing to input image data, comprises: adding means for adding any signal value in a range of predetermined lower limit and upper limit in every pixel, to each pixel value of input image data; measuring means for measuring gradation distribution divided in a plurality of distribution ranges on the basis of gradation values of a predetermined number of pixels to which the signal values are added by the adding means; and generating means for generating gradation correction data for correcting the input image data in each pixel of the predetermined number on the basis of the gradation distribution measured by the measuring means.

### BACKGROUND OF THE INVENTION

1. Field of the Invention

The invention relates to an image forming apparatus and an image forming method for forming output image data by processing input image data as predetermined.

2. Description of the Related Art

Conventionally, in television and other video display apparatus, video signals have been processed by gradation conversion. Such gradation correction processing is to process the video signal by predetermined gradation conversion in consideration of display characteristic, contrast of image data, and degree of gradation. For example, in the technology called black expansion, expression of black is emphasized by assigning a greater number of black gradations for video signal. In liquid crystal television, the broadcasting station side displays after converting the gradation (reverse gamma conversion) for returning the gradation conversion process of video signal to original signal, and returning the characteristic of video signal to linear characteristic. For gradation correction processing, generally, a look-up table (LUT) is used. The LUT is composed of a set of input and output corresponding to the input, and when data is entered, output data corresponding to the input data is issued. The LUT used in video display apparatus or the like is often designed so that the input and output characteristic may draw a curve, and hence it is generally called gamma conversion curve or gamma curve.

Recently, a new technique called dynamic gamma process is proposed, which is intended to execute optimum gradation correction processing in each scene (frame) of video. This is generally intended to correct the input data so that each scene image may be optimized visually depending on the degree of distribution of pixels in each scene or degree of change between scenes.

Japanese Patent Application Publication No. 7-99862 discloses a gradation correction apparatus having a recursive filter circuit. Japanese Patent Application Publication No. 7-99862 discloses a gradation correction apparatus having a circuit for forming an image on the basis of frequency distribution, and a recursive filter for suppressing oscillation of signal after correction due to fluctuation of frequency distribution by noise or the like. Furthermore, the gradation correction apparatus also includes a scene change detecting circuit for following up video scene changes.

Japanese Patent Application Laid-Open No. 2001-103338 discloses an image quality correcting circuit having a change suppressing part. Japanese Patent Application Laid-Open No. 2001-103338 discloses an image quality correcting circuit having a circuit for forming an image on the basis of frequency distribution, and a change suppressing part for suppressing deterioration of image quality due to extreme changes of brightness by image correction by extreme change of distribution state.

Japanese Patent Application Laid-Open No. 7-77963 discloses an image processing method for detecting the gradation distribution of luminance of image when displaying input video signal data on liquid crystal panel, and detecting the frequency of gradation in each predetermined gradation region of detected gradation distribution. This Japanese Patent Application Laid-Open No. 7-77963 judges if the frequency of gradation in each predetermined region is over the predetermined reference value or not. This judging is intended to vary the output gradation corresponding to input gradation in the look-up table for gradation conversion. That is, the process is intended to change the gamma conversion curve depending on the frequency distribution.

### SUMMARY OF THE INVENTION

The problems to be solved by the invention are described by referring to FIG. 9 and FIG. 10. FIG. 9 and FIG. 10 show gradually rising steps of luminance of video signal having luminance value of black in one entire screen, indicating (a) frequency distribution of luminance value of one screen (FIG. 9A, FIG. 10A), (b) frequency distribution (histogram) of luminance value defined by four classes (FIG. 9B, FIG. 10B), and (c) gamma conversion curve calculated on the basis of the histogram (FIG. 9B, FIG. 10B).

That is, FIG. 9B shows a concentrated state of frequency in a certain gradation value. Due to elevation of luminance of video signal, the gradation value of concentrated frequency is changing across the boundary of classes. In this case, in the method of correcting the gradation on the basis of frequency distribution, fluctuation of frequency distribution directly leads to large variations in characteristic of gradation conversion. This state is shown in FIG. 9C. FIG. 9C is a gamma conversion curve for converting the input gradation value calculated on the basis of frequency distribution shown in FIG. 9B into output gradation value. When the determined gamma conversion curve is changed largely, the contrast of the formed image is changed significantly. This image change causes flickering of image, and the image quality may deteriorate.

FIG. 10 shows a case of luminance fluctuations settling within a specific class range. In this case, as shown in FIG. 10A, luminance of actual input image is changed, but the frequency distribution of luminance in specific class is not changed as shown in FIG. 10B. Accordingly, without following up changes of image, the gradation conversion is always uniform as shown in FIG. 10C. As a result, there is a problem that image cannot be formed favorably depending on changes of image data.

The recursive filter disclosed in Japanese Patent Application Publication No. 7-99862, and the change suppressing part disclosed in Japanese Patent Application Laid-Open No. 2001-103338 could not solve these problems. The image forming method disclosed in Japanese Patent Application Laid-Open No. 7-77963 discloses determination of luminance level of input data in frequency distribution in a predetermined class unit. However, the technology disclosed in Japanese Patent Application Laid-Open No. 7-77963 is a technology of improving the dark contrast of image particularly small in gradation distribution at low luminance side, by flattening the distribution of luminance of image. That is, in any video signal data, the luminance is averaged uniformly in the class not exceeding a reference value, and matched to a specific input and output gradation conversion characteristic. Hence it cannot be applied in compilation of gamma conversion data depending on the characteristic of video signal as shown in FIG. 9 or FIG. 10.

The invention is devised to solve these problems, and it is hence an object thereof to present an image forming apparatus and an image forming method capable of forming an image favorably by following up changes of video signal.

To achieve above-mentioned object, according to the present invention, there is preferably provided an image forming apparatus for executing gradation correction processing to input image data, comprising: adding unit adapted to add any signal value in a range of predetermined lower limit and upper limit in every pixel, to each pixel value of the input image data; measuring unit adapted to measure gradation distribution divided in a plurality of distribution ranges on the basis of gradation values of a predetermined number of pixels to which the signal values are added by the adding unit; and generating unit adapted to generate gradation correction data for correcting the input image data in each pixel of the predetermined number on the basis of the gradation distribution measured by the measuring unit.

According to the invention, there is preferably provided an image forming apparatus for executing gradation correction processing to input image data, comprising: measuring unit adapted to measure gradation distribution of a predetermined number of pixels in each pixel of the predetermined number in input image data; and generating unit adapted to generate gradation correction data for correcting the input image data in each pixel of the predetermined number on the basis of the gradation distribution measured by the measuring unit, wherein the gradation distribution is divided into a plurality of distribution ranges by a predetermined range boundary value, and the predetermined range boundary value is varied in each pixel measured by the measuring unit in a predetermined lower limit and upper limit range.

According to the invention, there is preferably provided an image forming method for executing gradation correction processing to input image data, comprising: an adding step of adding any signal value in a range of predetermined lower limit and upper limit in every pixel, to each pixel value of the input image data; a measuring step of measuring gradation distribution divided in a plurality of distribution ranges on the basis of gradation values of a predetermined number of pixels to which the signal values are added at the adding step; and a generating step of generating gradation correction data for correcting the input image data in each pixel of the predetermined number on the basis of the gradation distribution measured at the measuring step.

According to the invention, there is preferably provided an image forming method for executing gradation correction processing to input image data, comprising: a measuring step of measuring gradation distribution of a predetermined number of pixels in each pixel of the predetermined number in input image data; and a generating step of generating gradation correction data for correcting the input image data in each pixel of the predetermined number on the basis of the gradation distribution measured at the measuring step, wherein the gradation distribution is divided into a plurality of distribution ranges by a predetermined range boundary value, and the predetermined range boundary value is varied in each pixel measured at the measuring step in a predetermined lower limit and upper limit range.

### DESCRIPTION OF THE DRAWINGS

FIG. 1 is a block diagram of image forming apparatus according to embodiment 1 of the invention;

FIG. 2 is a block diagram of image forming apparatus according to embodiment 2 of the invention;

FIG. 3 is a block diagram of image forming apparatus according to embodiment 3 of the invention;

FIG. 4 is a block diagram of image forming apparatus according to embodiment 3 of the invention;

FIG. 5 is an explanatory diagram of discrete data according to embodiments 1 and 2 of the invention;

FIG. 6 is an explanatory diagram of histogram according to embodiments 1 and 2 of the invention;

FIGS. 7A to 7C are explanatory diagrams of histogram averaging method in a known art;

FIGS. 8A to 8L are explanatory diagrams of embodiments 1 and 2 of the invention;

FIGS. 9A to 9C are explanatory diagrams of problems in the related art;

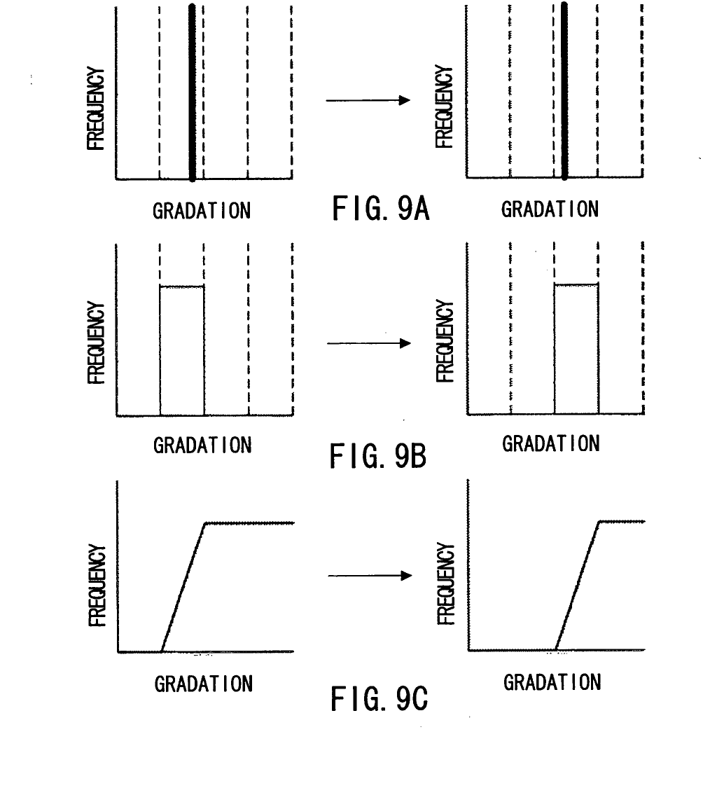

FIGS. 10A to 10C are explanatory diagrams of problems in the related art;

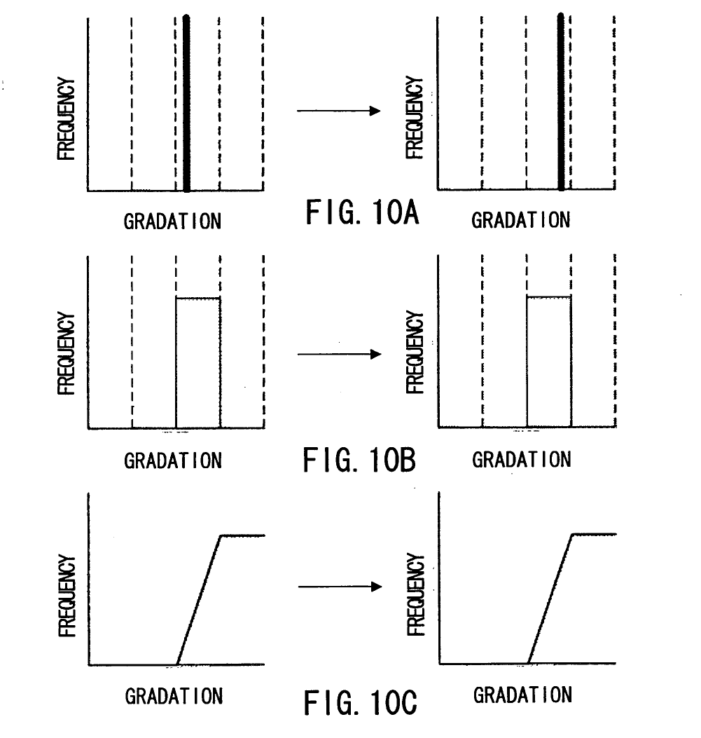

FIG. 11 is an explanatory diagram of gradation conversion unit according to embodiments 1, 2 and 3 of the invention;

FIG. 12 is an explanatory diagram of operation in embodiments 2 and 3 of the invention;

FIG. 13 is an explanatory diagram of operation in embodiments 2 and 3 of the invention;

FIG. 14 is an explanatory diagram of operation in embodiments 2 and 3 of the invention;

FIG. 15 is an explanatory diagram of operation in embodiments 2 and 3 of the invention;

FIG. 16 is an explanatory diagram of pulse width modulation drive according to embodiment 3 of the invention;

FIG. 17 is an explanatory diagram of pulse width modulation drive according to embodiment 3 of the invention;

FIG. 18 is an explanatory diagram of gamma characteristic control of SED by drive voltage control according to embodiment 3 of the invention;

FIG. 19 is an explanatory diagram of gamma characteristic control of SED by drive voltage control according to embodiment 3 of the invention;

FIG. 20 is an explanatory diagram of gamma characteristic control of SED by drive voltage control according to embodiment 3 of the invention;

FIG. 21 is an explanatory diagram of gamma characteristic control of SED by drive voltage control according to embodiment 3 of the invention; and

FIG. 22 is an explanatory diagram of gamma characteristic control of SED by drive voltage control according to embodiment 3 of the invention.

### DETAILED DESCRIPTION OF THE INVENTION

Preferred embodiments of the invention are described below.

### Embodiment 1

The image forming method of the invention includes an image forming method using frequency distribution, such as dynamic gamma, black expansion, and white expansion, and the dynamic gamma is, in particular, preferred for the invention because it uses frequency distribution having a plurality of classes.

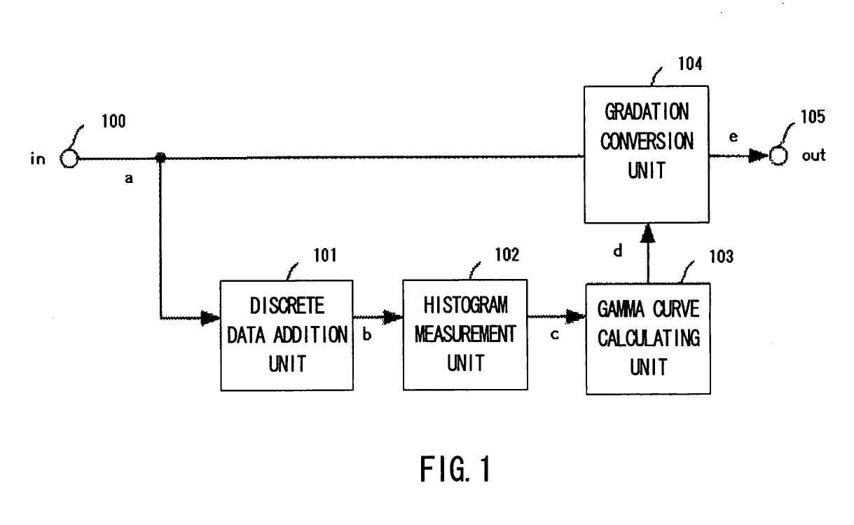

An embodiment of the invention is specifically described below by referring to an example of dynamic gamma in FIG. 1.

In FIG. 1, reference numeral 100 denotes an input terminal of luminance data of video, 101 denotes a discrete data addition unit, 102 denotes a histogram measurement unit, 103 denotes a gamma curve calculating unit, 104 denotes a gradation conversion unit, and 105 denotes an output terminal of gradation converted luminance data. In the diagram, a to e indicate individual data, denotes luminance data, b denotes discrete luminance data, c denotes histogram data, d denotes gamma conversion curve, and e denotes output luminance data.

In the embodiment, luminance data a of each pixel for composing image data for calculating frequency distribution is entered in the input terminal 100. The luminance data a is entered in the discrete data addition unit 101 as adding means in every pixel, and in the gradation conversion unit 104 as gradation correcting means. In the embodiment, color difference data is not processed particularly. By processing only the luminance data, dynamic gamma is realized. However, the invention can be also applied in other signal data than luminance data. For example, individual gradation data of R, G, and B can be used.

The discrete data addition unit 101 adds discrete data to each one of luminance data a, and generates discrete luminance data b. The discrete data is not specific fixed value, but is arbitrary data such as Gaussian distribution or ramp waveform varying within a specific distribution by every addition. If the value after addition of discrete data is smaller than 0, the value is limited to 0. If exceeding the maximum value of luminance data, too, the value is limited to the maximum value. To realize the invention, numerical data varying within predetermined range may be added to the luminance value of each pixel. For example, a random number having a specific amplitude is generated, and the random number is added to the luminance value of each pixel. The degree of amplitude should be determined appropriately by using the class width or evaluation result of image quality. In the embodiment, the distribution range of discrete data is set larger than the class width of histogram determined in the histogram measurement unit as measuring means.

Thus, by individually adding data varying in a specific range to the luminance data of each pixel of input video signal, the data after addition is dispersed. Therefore, even in the case of input video signal showing frequency only in a specific class, the signal data after addition of discrete data also appears as frequency in other class. The histogram measurement unit 102 measures the discrete luminance data b for the period of one frame, and generates histogram data c.

The gamma curve calculating unit 103 as generating means calculates by using the histogram data c, and obtains gamma conversion curve d. The method of calculation is described later.

Using this gamma conversion curve d, the gradation conversion unit 104 converts the gradation of input luminance data a, and issues output luminance data e to the output terminal 105. The invention is more specifically described below by referring to specific examples.

The input luminance data a is supposed to be 8-bit data.

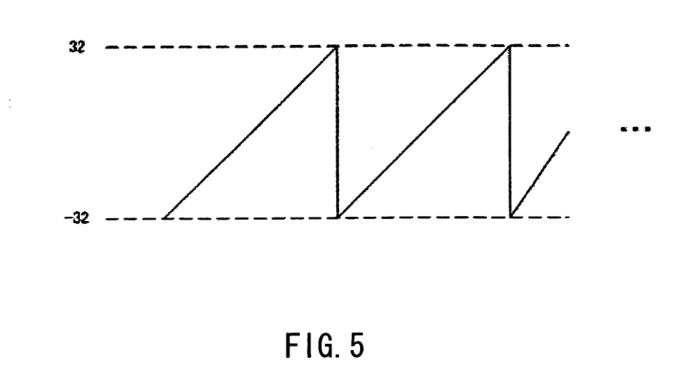

The discrete data addition unit 101 adds discrete data to input luminance data a. The discrete data is not specific fixed value, but is data varying by every addition. Herein, as shown in FIG. 5, discrete data is ramp waveform data varying between −32 and +32.

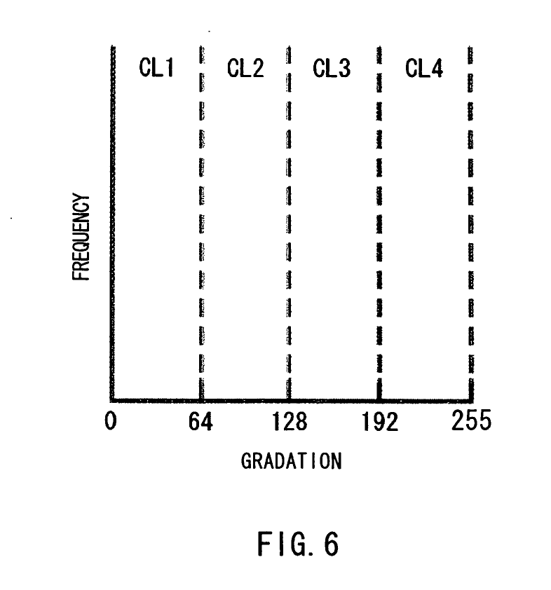

The histogram measurement unit 102 counts the discrete luminance data b to which discrete data is added for the period of one frame, and generates histogram data c using the number of pixels in each luminance value as frequency. The histogram generated by the histogram measurement unit 102 is predetermined the range of luminance values in four regions (classes), 0 to 63, 64 to 127, 128 to 191, and 192 to 255. It is shown in FIG. 6. In FIG. 6, CL1, CL2, CL3, and CL4 are classes of the histogram. That is, the luminance values corresponding to CL1 are 0 to 63, luminance values corresponding to CL2 are 64 to 127, luminance values corresponding to CL3 are 128 to 191, and luminance values corresponding to CL4 are 192 to 255. The histogram measurement unit 102 generates data by counting the number of pixels composing the luminance value corresponding to the range of each class of histogram shown in FIG. 6.

The gamma curve calculating unit 103 calculates and generates an appropriate gamma conversion curve for gradation correction of image of the one frame from the histogram data c. Generation of gamma conversion curve is explained, in this example, by referring to the known histogram averaging method. Meanwhile, the gamma conversion curve may be calculated by any other method.

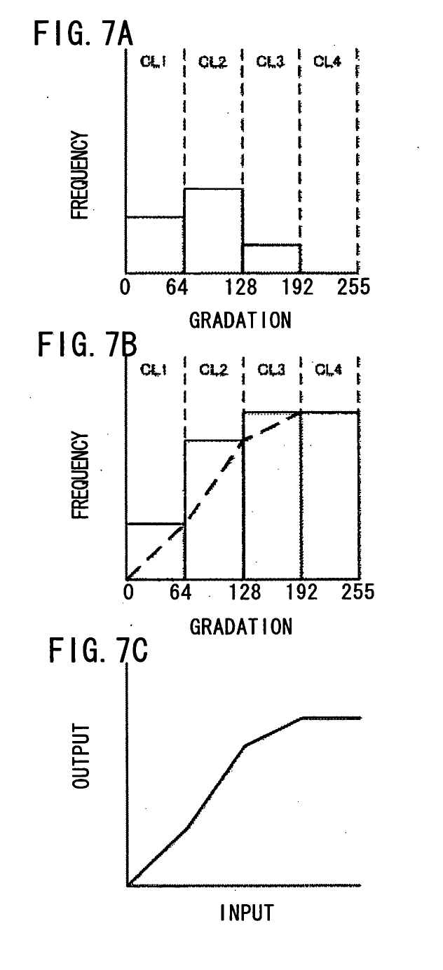

FIG. 7 explains the histogram averaging method. FIG. 7A is a histogram measured by the histogram measurement unit. From the measured histogram, a cumulative histogram is calculated. FIG. 7B shows a cumulative histogram of FIG. 7A. A cumulative histogram is a frequency distribution determined by cumulatively adding the frequency in each class, using the number of pixels calculating the histogram as maximum value. In the histogram averaging method, as shown by broken line in FIG. 7B, the gamma conversion curve is determined by interpolating the cumulative histogram.

The maximum value (maximum frequency) of broken line of FIG. 7B is equal to the total number of pixels of the screen, and it is scaled to the output maximum value. Suppose, for example, the total number of pixels of the screen to be 640×480=307200 pixels. That is, the maximum value of broken line of FIG. 7B is 307200. To use it as gamma curve, it is scaled to the output maximum value of 255. Specifically, the curve of broken line is multiplied by (255/307200) times. The curve thus scaled becomes the gamma conversion curve d.

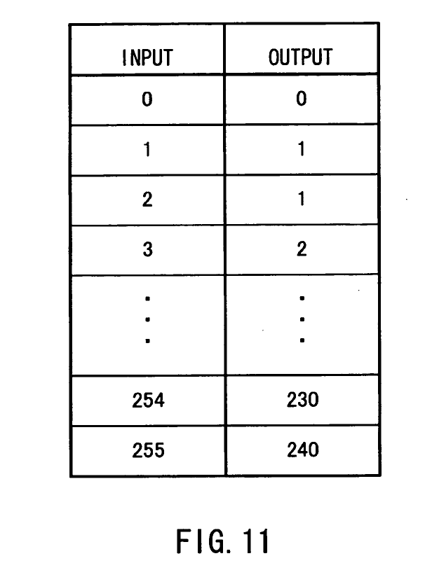

The gradation conversion unit 104 processes input image data a by gamma conversion by using this gamma conversion curve d. Specifically, the gradation conversion unit 104 operates as follows. The gradation conversion unit 104 is composed of LUT consisting of a set of input and output as shown in FIG. 11. The input in the diagram corresponds to luminance data a, and the output is equivalent to output luminance data e. The LUT, when input luminance data a is entered in the gradation conversion unit 104, issues the output luminance data e corresponding to the input luminance data a to the output terminal 105. The gradation conversion unit 104 receives the gamma conversion curve d from the gamma curve calculating unit 103 in every frame, and rewrites the output of the LUT by the value of the gamma curve. In this constitution, the gradation conversion process on the basis of various gamma conversion curves d is executed.

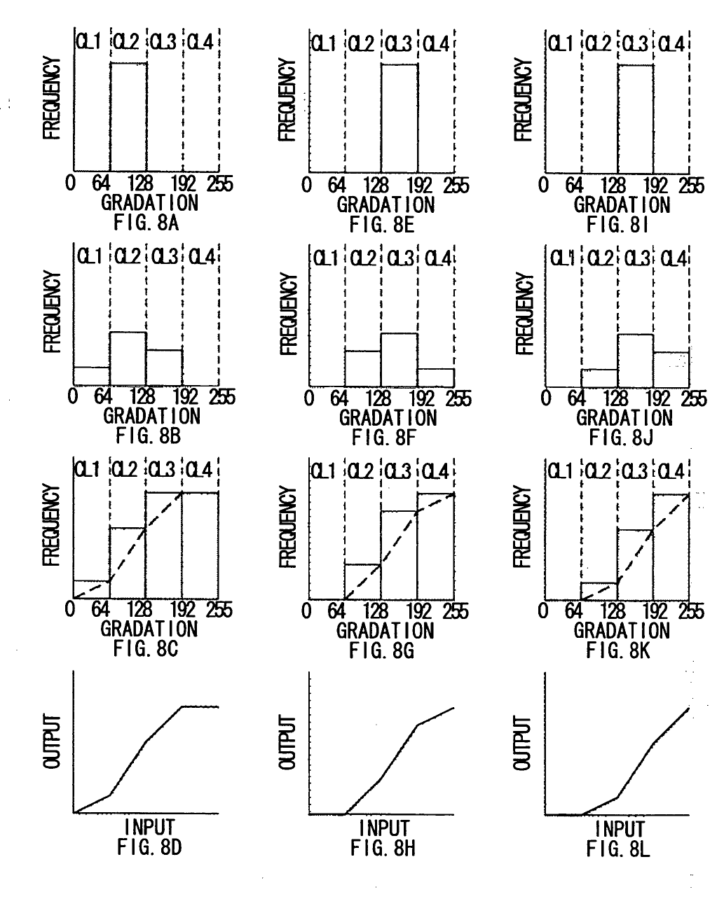

Referring further to FIG. 8, as explanation of the embodiment, signal changes in each block are described below.

FIGS. 8A to 8D are histograms and gamma curves in each block supposing the input image data a to be solid image of luminance of 127. The histogram of solid image of luminance 127 is usually as shown in FIG. 8A. In the invention, by adding discrete data to luminance data, a histogram having frequency distributed in other class as shown in FIG. 8B is determined in histogram measurement unit 102. Using this histogram, a cumulative histogram calculated in the gamma curve calculating unit 103 is obtained as shown in FIG. 8C. This gamma conversion curve d is shown in FIG. 8D.

FIGS. 8E to 8H show solid images of luminance 129 as a result of variation of input image data a. The gradation of concentration of frequency is changing across the class boundary from 127 to 129, but the gamma curve does not change significantly as shown in FIG. 8D and FIG. 8H. This is the effect of dispersion of luminance distribution by adding the discrete data varying from luminance value within predetermined distribution to each pixel. As a result, if the image data varies beyond the class boundary, the degree of gamma correction varies significantly, so that the problem of deterioration of image quality due to obvious changes of image can be improved.

FIGS. 8I to 8L show solid images of luminance 191 as a result of variation of input image data a.

The gradation of concentration of frequency is changing from gradation 129 to 191, but this change is variation of image data within class CL3. Therefore, in the conventional method, only the same gamma conversion curve was obtained in both cases. However, by employing the method of the invention, the gamma conversion curve changes between FIG. 8H and FIG. 8L. Not to mention, this is because the luminance distribution is dispersed by adding the discrete data changing within specific distribution with respect to the luminance value to each pixel. Hence, the problems described in FIG. 11 can be solved by the invention.

As described herein, in the embodiment, discrete data is added to the luminance value of each pixel in one frame of input video signal data, and the histogram of pixels added discrete data is measured, and hence an optimum gamma conversion curve can be generated. It hence solve the problems of the related art, such as excessive changes of gradation correction process leading to poor and undesired images or inappropriate gradation correction.

### Embodiment 2

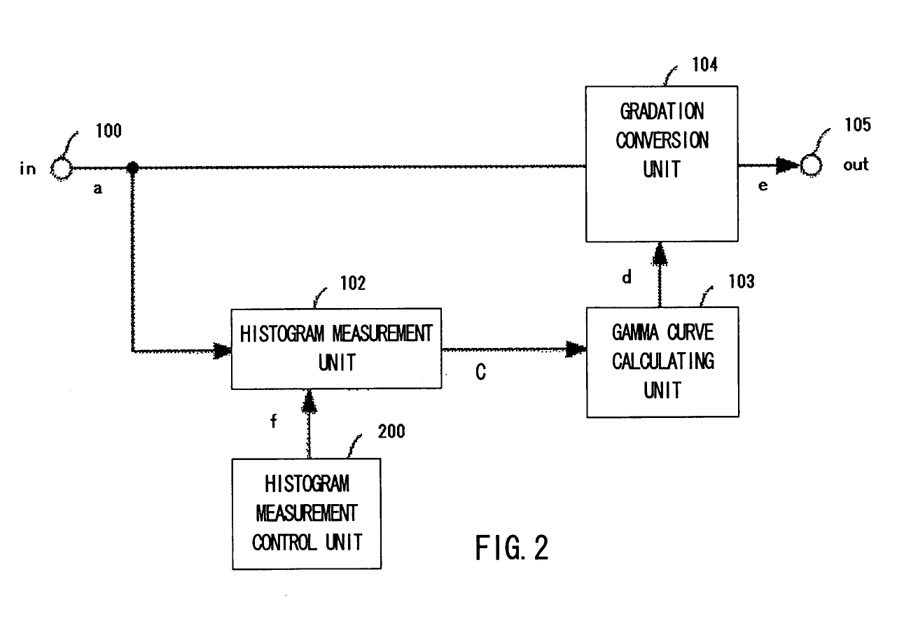

In other embodiment of the invention, an example of dynamic gamma is specifically described below by referring to FIG. 2. The foregoing embodiment 1 is intended to execute optimum gradation correction processing by intentionally destroying distribution by adding discrete data to input luminance data. By contrast, this embodiment brings about the same effects as in embodiment 1 by varying the range of class of histogram, without processing the input luminance data.

In FIG. 2, a histogram measurement control unit 200 is provided as measuring means. Also in the diagram, f denotes a histogram measurement control signal. Reference numerals 100, 102 to 105, and a, c to e are same as in the embodiment in FIG. 1 and the explanation is not repeated here.

In this embodiment, the histogram measurement control unit 200 controls to change the boundary value of each class of histogram every time the histogram measurement unit 102 counts the luminance data of pixels contained in one frame.

Same as in embodiment 1, the luminance data a is explained as 8-bit data in this embodiment.

The histogram measurement control unit 200 controls to vary the range of each class of histogram every time the histogram measurement unit 102 counts the luminance value of pixel data of the object of calculation of histogram. The default range of each class is as shown in FIG. 6.

In FIG. 6, the upper limit of class CL1 is CL1u and lower limit is CL1d, the upper limit of class CL2 is CL2u and lower limit is CL2d, the upper limit of class CL3 is CL3u and lower limit is CL3d, and the upper limit of class CL4 is CL4u and lower limit is CL4d. The variation value of each class is alpha. At this time, the variation range of each class is as follows.

CL1d after variation=default CL1d=0

CL1u after variation=default CL1u+alpha

CL2d after variation=default CL2d+alpha=CL1u after variation

CL2u after variation=default CL2u+alpha

CL3d after variation=default CL3d+alpha=CL2u after variation

CL3u after variation=default CL3u+alpha

CL4d after variation=default CL4d+alpha=CL3u after variation

CL4u after variation=default CL4u=255

The variation value “alpha” is ramp waveform data varying between −32 and +32 as shown in FIG. 5. Not to mention, the variation range is not limited to −32 to +32. Aside from ramp waveform data, amplitude function or random number can be also used.

At this time, if the upper limit or lower limit of each class becomes smaller than 0, the value is limited to 0. If larger than 255, the value is limited to 255. If the upper limit of class is 0, the pixel of which luminance data value is 0 should be the count value of one class higher (for example, if the upper limit of CL1 is 0, the count value of CL2). If the lower limit of class is 255, the count value of one class lower is used (for example, if the lower limit of CL4 is 255, the count value of CL3).

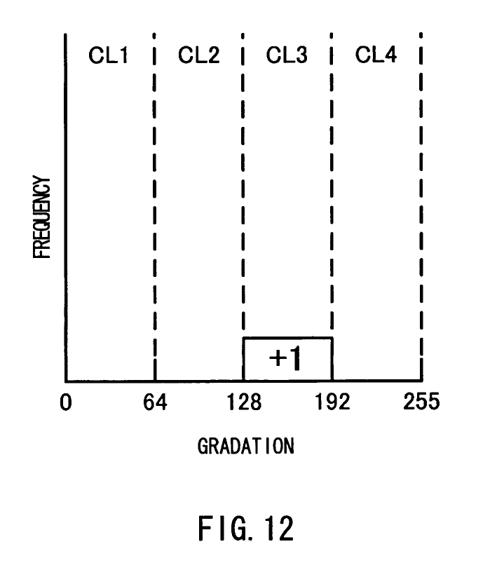

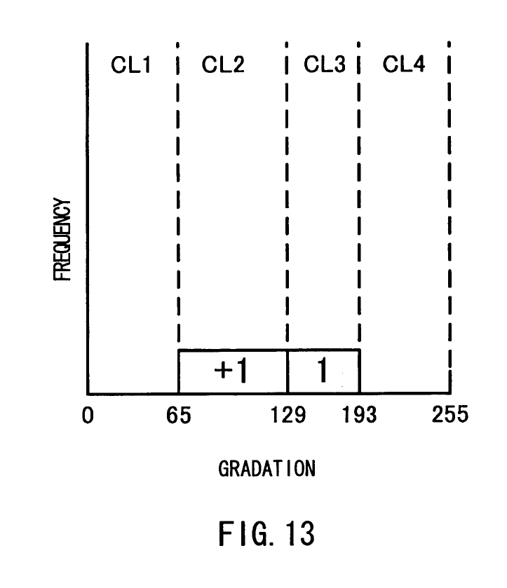

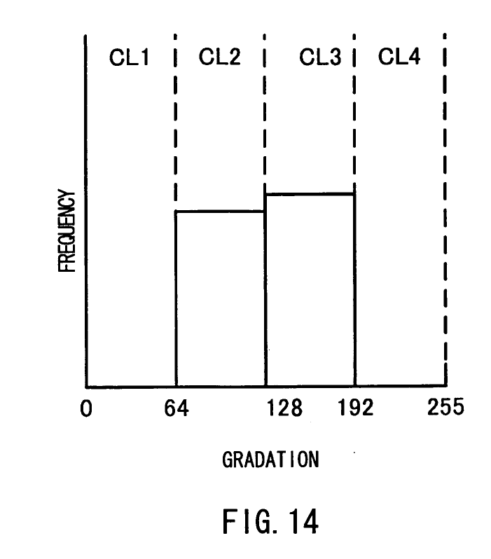

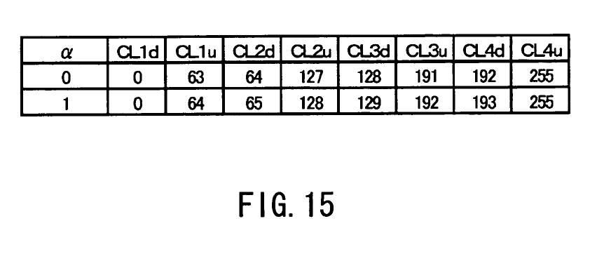

Referring to the drawings, the operation of the embodiment is explained. FIG. 12 shows a class range in the case of alpha=0, and FIG. 13 shows a class range in the case of alpha=1. FIG. 14 is a histogram when measuring the luminance data for the period of one frame. FIG. 15 is a table showing the upper limit and lower limit of each class in the case of value of alpha.

In the class range shown in FIG. 12, when data of luminance 128 is entered in the histogram measurement unit, the histogram measurement unit increments the count value of class CL3 by +1. The histogram measurement unit changes the variation value “alpha” after counting every data. In this embodiment, since the ramp waveform data shown in FIG. 5 is used as variation value alpha, alpha is 1. In this case, the range of each class is as shown in FIG. 13. At this time, when data of 128 is entered, the histogram measurement unit increments the count value of CL2 by +1.

Similarly, every time counting the luminance data, the upper limit and lower limit of each class can be changed. Even if luminance data of same value is counted, the class to be counted can be changed. During execution of counting, by varying the boundary value of class, substantially same effects as when discrete data is added to luminance data can be obtained as in embodiment 1. In this embodiment, however, only the boundary value is varied virtually, and the number of pixels is counted in the object class, and as the histogram for obtaining the gamma conversion curve d finally, a histogram having default class boundary value is used. Therefore, if the pixel of luminance value 128 is counted in CL2 due to variation of class boundary value, when returned to the default histogram, it remains to be counted as the pixel of CL2.

Hence, if all pixels of one frame are entered as data of luminance value 128, histogram data dispersed into CL2 and CL3 can be obtained as shown in FIG. 14.

Therefore, in this embodiment, too, dispersed histogram data can be obtained. That is, from this histogram data, same as in embodiment 1, the gamma conversion curve capable of improving the related art can be obtained. Hence, in this embodiment, same as in embodiment 1, it is possible to solve the problems of related art, such as excessive change of gradation correction processing to cause undesired worsening of image, or failure in optimum gradation correction.

### Embodiment 3

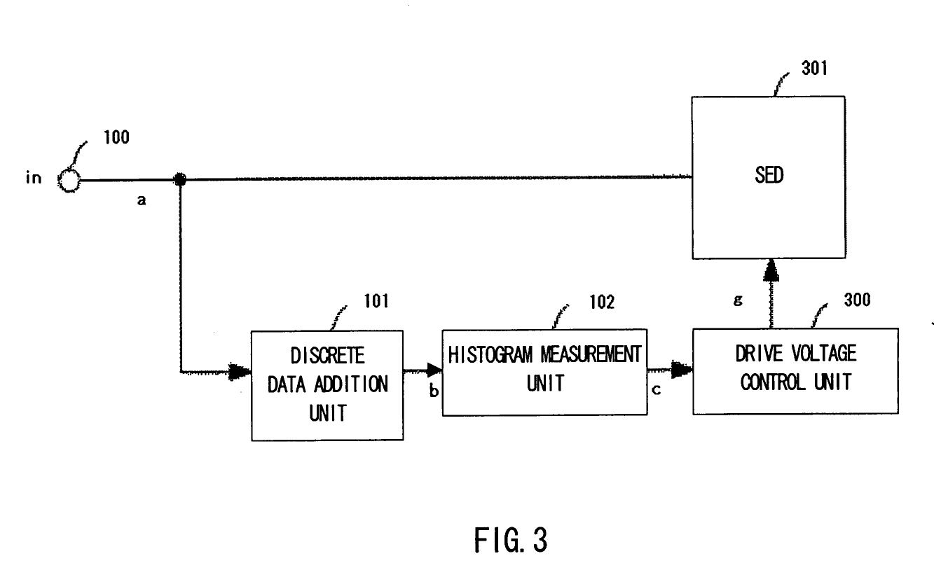

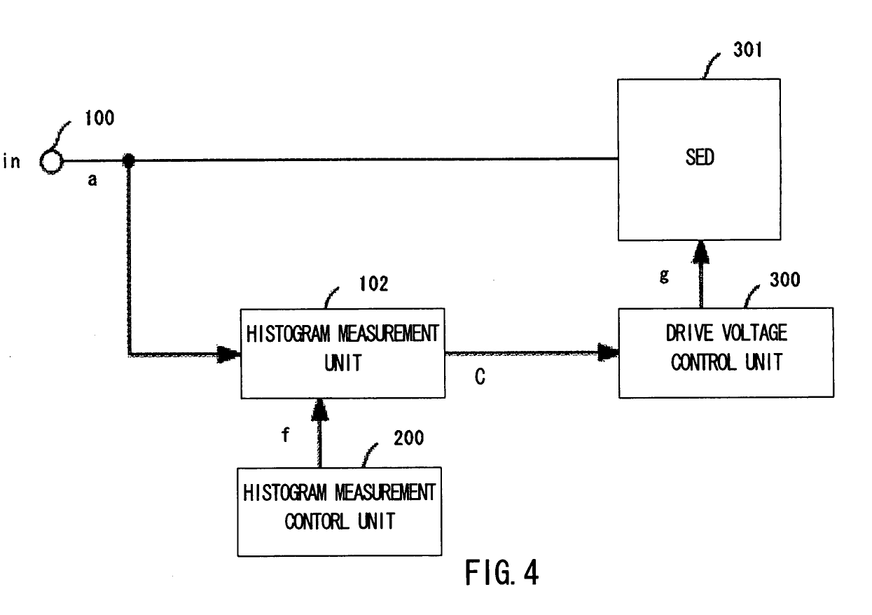

Subsequently, a different embodiment of the invention is explained by referring to an example of dynamic gamma shown in FIG. 3 and FIG. 4.

In FIG. 3 and FIG. 4, reference numeral 300 denotes a drive voltage control unit as gradation correction means, and 301 denotes SED (Surface conduction Electron-emitter Display). In the diagram, g denotes a drive voltage control signal of SED. FIG. 3 shows, same as in embodiment 1, the constitution of the embodiment applied in measurement of histogram by adding discrete data to luminance data. FIG. 4 shows, same as in embodiment 2, the constitution of the embodiment applied in measurement of histogram by varying the boundary value of class of histogram. Therefore, reference numerals 100 to 102, 200, and a to c and f are same as in FIG. 1 and FIG. 2, and the explanation is not repeated here.

The SED 301 is a display device capable of varying the gamma characteristic by drive voltage. The mechanism of SED is explained below.

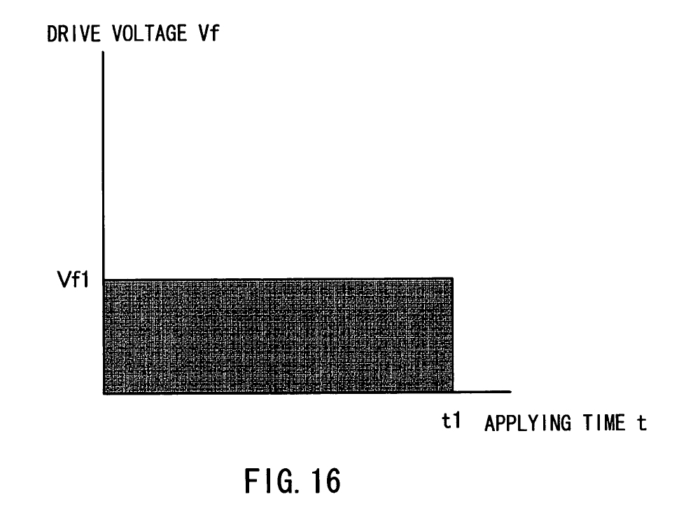

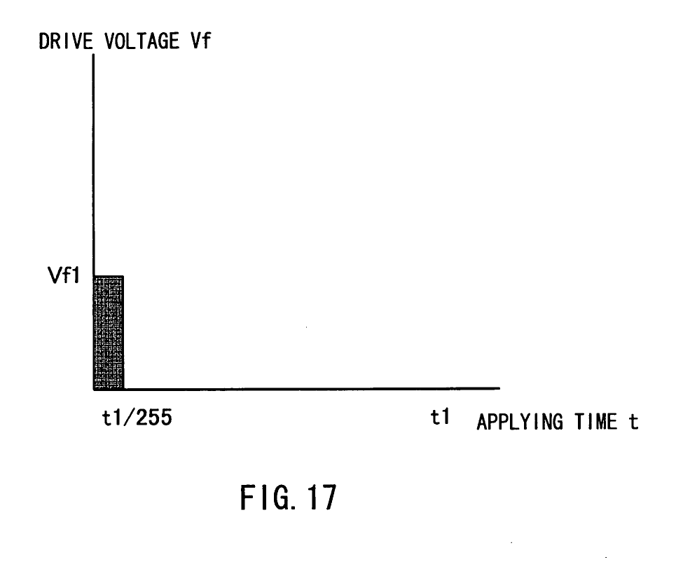

The driving method of SED includes pulse width modulation (PWM) drive method. The PWM is a method of controlling the luminescence intensity by the applying time of voltage by making use of the linear relation of applying time and luminescence intensity of phosphor when voltage is applied to the electron emission source. The voltage applied at this time is called drive voltage. The PWM is further described by referring to FIG. 16. FIG. 16 is a diagram showing the relation of applying time t of drive voltage Vf and luminescence intensity. The axis of abscissas denotes the applying time, and the axis of ordinates denotes the drive voltage. The luminance in the condition of applying time t1 and drive voltage Vf1 is expressed in the shaded area enclosed by t1 and Vf1. Usually, in PWM, the drive voltage is kept constant, and the luminescence intensity is controlled by changing the applying time only. Since the luminescence intensity and applying time are in linear relation, the pixel values of image data are assigned uniformly in applying time, so that the luminescence intensity and image data may correspond to each other. That is, when the image data is 8 bits, and the applying time is t1, if the luminescence intensity is designed at peak L1, luminescence intensity of L1 is obtained at drive voltage of Vf and applying time of t1 in the case of pixel value of 255. When the pixel value is 1, luminescence intensity of L1/255 can be obtained at drive voltage of Vf and applying time of t1/255 (FIG. 17). Herein, the pixel value refers to each value of R, G, and B. The SED has phosphors of three colors of R, G and B per pixel. Hence, in all pixels, R, G and B are individually controlled, and images are formed.

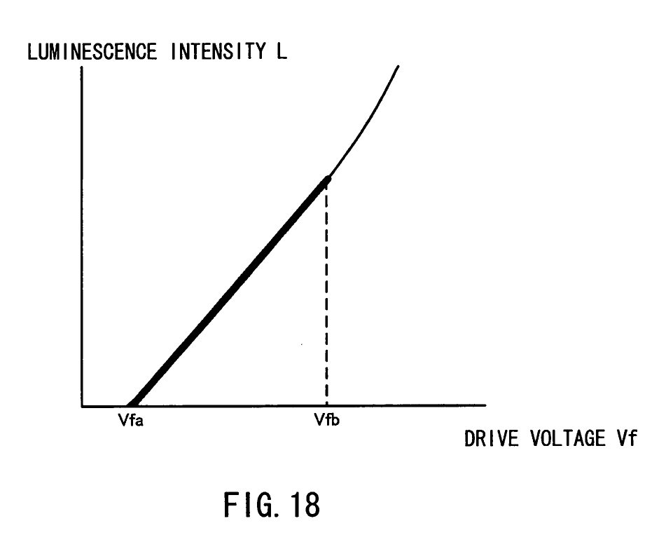

Meanwhile, by varying the drive voltage Vf which is usually constant, a method is proposed to provide the SED with gamma characteristic. This is explained below. The relation of drive voltage and luminescence intensity is plotted in a downward convex increase curve as shown in FIG. 18. In this embodiment, drive voltage Vf is used between Vfa and Vfb in which the relation is almost linear between drive voltage Vf and luminescence intensity L.

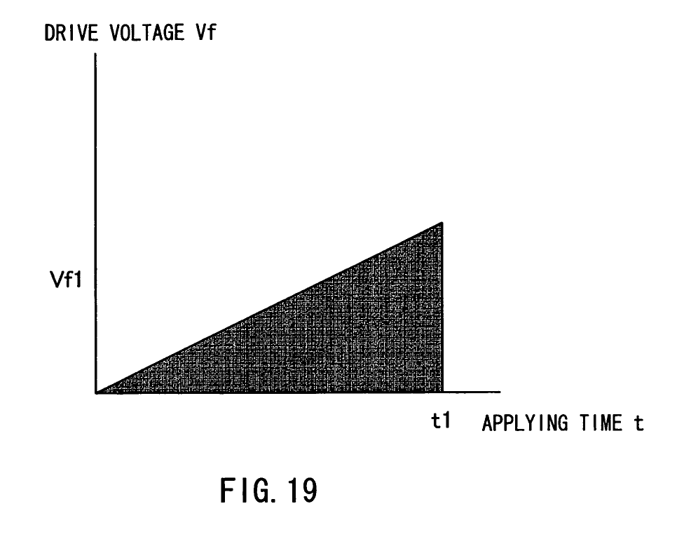

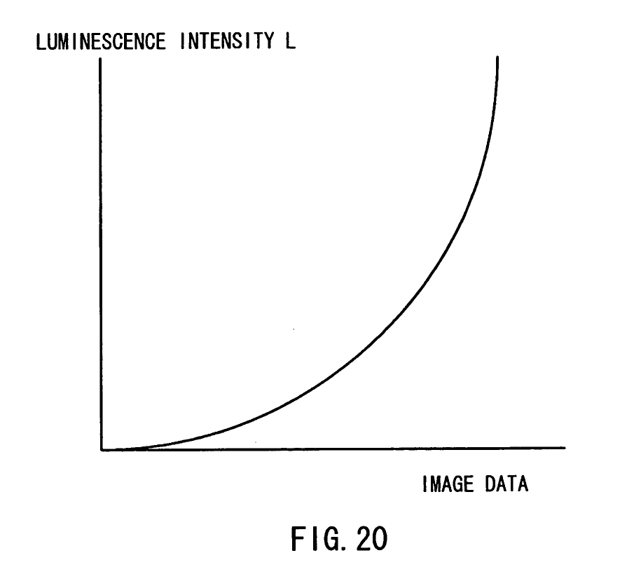

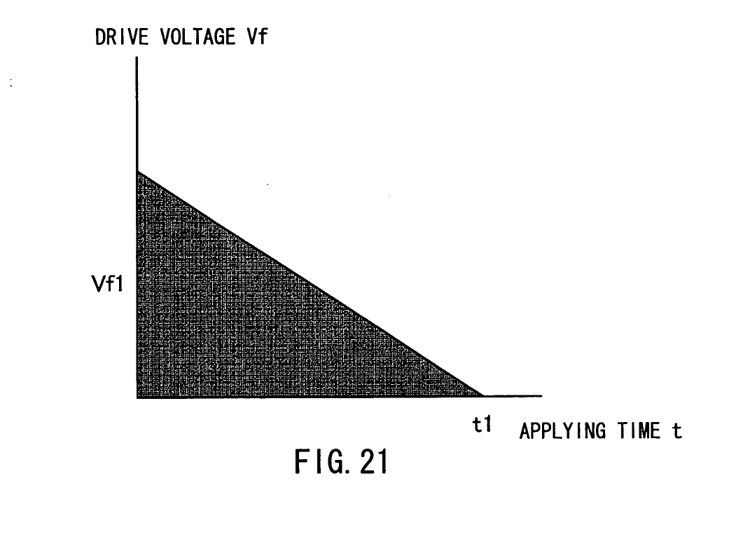

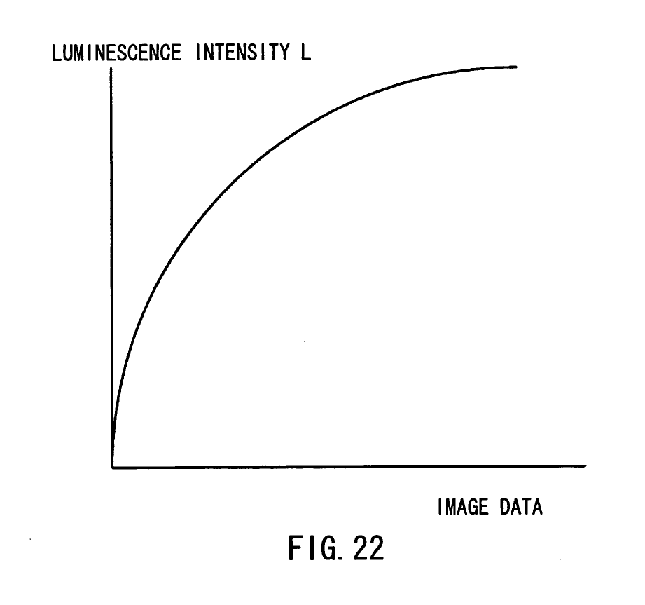

Herein, the drive voltage Vf being use data specific value regardless of applying time is controlled to increase along with lapse of time as shown in FIG. 19. As a result, the increment of luminescence intensity per unit time is increased. Therefore, when each value of 8 bits of image data is uniformly assigned in the applying time, the relation of pixel value of image data and luminescence intensity draws a downward convex increase curve as shown in FIG. 20. Or when the drive voltage Vf is controlled to decrease along with lapse of time as shown in FIG. 21, the relation of image data and luminescence intensity draws an upward convex increase curve as shown in FIG. 22. By controlling the value of drive voltage Vf in such manner, the SED is provided with gamma characteristic.

Or when the relation of applying time and drive voltage is controlled in each frame, the gamma characteristic of SED can be changed in each frame.

Based on the above-described fact, the explanation of the embodiment continues. The drive voltage control unit 300 generates drive voltage control signal g on the basis of histogram data c. The drive voltage control signal g is a signal for instructing the drive voltage Vf in each applying time.

The method of generating drive voltage control signal g from histogram data c is explained. First, same as in embodiment 1 and embodiment 2, a gamma conversion curve is obtained from histogram data by histogram averaging method. This gamma conversion curve is supposed to be f(x). Herein, x is an input gradation. Next, increase function g (x) is obtained to show an increment per gradation of f(x). This function g(x) is expressed as follows.
g(x)=f(x)−f(x−1);

however, when x=0, g(x) is 0.

The drive voltage control unit supplies this g(x) to the SED in every frame as drive voltage control signal g. The SED multiplies this drive voltage control signal by Vf1 to obtain a drive voltage for driving the SED.

Thus, from the histogram data dispersed in each frame, gamma conversion curve d is obtained same as in embodiment 1 and embodiment 2. From this gamma conversion curve d, drive voltage control signal g is generated. By controlling the SED by using this drive voltage control signal g, it is possible to solve the problems of related art, such as excessive change of gradation correction processing to cause undesired worsening of image, or failure in optimum gradation correction due to gradation correction processing not following up the changes of image.

In the foregoing embodiments, the discrete data addition unit, histogram measurement unit, gamma conversion curve calculating unit, and gradation conversion unit can be all composed of hardware. Similar effects can be obtained by applying the program for executing the functions of each part in an applicable computer environment. Not to mention, the invention can be realized by using both hardware and software.

In the embodiments, luminance data of input video signal is processed. The invention is, however, not limited to processing of luminance data. The number of classes or the width of class can be freely selected by any party carrying out the invention.

As mentioned herein, gradation correction processing following up changes of video can be realized in any video. At the same time, images are formed favorably while suppressing deterioration of image quality due to excessive correction by gradation correction processing.

This application claims priority from Japanese Patent Application No. 2005-114220 filed Apr. 12, 2005 and Japanese Patent Application No. 2006-054624 filed Mar. 1, 2005, which are hereby incorporated by reference herein.

What is claimed is:

1. An image forming apparatus for executing gradation correction processing to input image data, comprising:
adding unit adapted to add any signal value in a range of predetermined lower limit and upper limit in every pixel, to each pixel value of the input image data;
measuring unit adapted to measure gradation distribution divided in a plurality of distribution ranges on the basis of gradation values of a predetermined number of pixels to which the signal values are added by said adding unit; and
generating unit adapted to generate gradation correction data for correcting the input image data in each pixel of the predetermined number on the basis of the gradation distribution measured by said measuring unit.

2. An image forming apparatus for executing gradation correction processing to input image data, comprising:
measuring unit adapted to measure gradation distribution of a predetermined number of pixels in each pixel of the predetermined number in input image data; and
generating unit adapted to generate gradation correction data for correcting the input image data in each pixel of the predetermined number on the basis of the gradation distribution measured by said measuring unit,
wherein the gradation distribution is divided into a plurality of distribution ranges by a predetermined range boundary value, and the predetermined range boundary value is varied in each pixel measured by said measuring unit in a range of a predetermined lower limit and upper limit.

3. An image forming apparatus of claim 1, wherein a gradation correction data is generated according to the distribution degree of the predetermined number of pixels in the plurality of distribution ranges.

4. An image forming apparatus of claim 2, wherein a gradation correction data is generated according to the distribution degree of the predetermined number of pixels in the plurality of distribution ranges.

5. An image forming apparatus of claim 1, wherein the signal value to be added by said adding unit is determined on the basis of a function of amplitude between the predetermined lower limit and upper limit.

6. An image forming apparatus of claim 2, wherein variation of the predetermined range boundary value is determined on the basis of a function of amplitude between the predetermined lower limit and upper limit.

7. An image forming apparatus of claim 1, further comprising gradation correcting unit adapted to execute gradation correction processing to the input image data by using the gradation correction data generated by said generating unit, wherein said gradation correcting unit executes gradation correction process in each pixel of the predetermined number in the input image data.

8. An image forming apparatus of claim 2, further comprising gradation correcting unit adapted to execute gradation correction processing to the input image data by using the gradation correction data generated by said generating unit, wherein said gradation correcting unit executes gradation correction process in each pixel of the predetermined number in the input image data.

9. An image forming apparatus of claim 7, wherein said gradation correcting unit adapted to generate a control signal for controlling a drive voltage on the basis of gradation correction data generated by said generating unit when the input image data is displayed in a display unit capable of adjusting the gamma characteristic by controlling the drive voltage.

10. An image forming apparatus of claim 8, wherein said gradation correcting unit adapted to generate a control signal for controlling a drive voltage on the basis of gradation correction data generated by said generating unit when the input image data is displayed in a display unit capable of adjusting the gamma characteristic by controlling the drive voltage.

11. An image forming method for executing gradation correction processing to input image data, comprising:
an adding step of adding any signal value in a range of predetermined lower limit and upper limit in every pixel, to each pixel value of the input image data;
a measuring step of measuring gradation distribution divided in a plurality of distribution ranges on the basis of gradation values of a predetermined number of pixels to which the signal values are added at the adding step; and
a generating step of generating gradation correction data for correcting the input image data in each pixel of the predetermined number on the basis of the gradation distribution measured at the measuring step.

12. An image forming method for executing gradation correction processing to input image data, comprising:
a measuring step of measuring gradation distribution of a predetermined number of pixels in each pixel of the predetermined number in input image data; and
a generating step of generating gradation correction data for correcting the input image data in each pixel of the predetermined number on the basis of the gradation distribution measured at the measuring step,
wherein the gradation distribution is divided into a plurality of distribution ranges by a predetermined range boundary value, and the predetermined range boundary value is varied in each pixel measured at the measuring step in a predetermined lower limit and upper limit range.

13. An image forming method of claim 11, wherein the gradation correction data is generated according to the distribution degree of the predetermined number of pixels in the plurality of distribution ranges.

14. An image forming method of claim 12, wherein the gradation correction data is generated according to the distribution degree of the predetermined number of pixels in the plurality of distribution ranges.

15. An image forming method of claim 11, wherein the signal value to be added at the adding step is determined on the basis of a function of amplitude between the predetermined lower limit and upper limit.

16. An image forming method of claim 12, wherein variation of the predetermined range boundary value is determined on the basis of a function of amplitude between the predetermined lower limit and upper limit.

17. An image forming method of claim 11, further comprising a gradation correcting step of executing gradation correction process of the input image data by using the gradation correction data generated at the generating step, wherein the gradation correcting step executes gradation correction process in each pixel of the predetermined number in the input image data.

18. An image forming method of claim 12, further comprising a gradation correcting step of executing gradation correction process of the input image data by using the gradation correction data generated at the generating step, wherein the gradation correcting step executes gradation correction process in each pixel of the predetermined number in the input image data.

19. An image forming method of claim 17, wherein the gradation correcting step generates a control signal for controlling the drive voltage on the basis of gradation correction data generated at the generating step when the input image data is displayed in a display unit capable of adjusting the gamma characteristic by controlling the drive voltage.

20. An image forming method of claim 18, wherein the gradation correcting step generates a control signal for controlling the drive voltage on the basis of gradation correction data generated at the generating step when the input image data is displayed in a display unit capable of adjusting the gamma characteristic by controlling the drive voltage.
